(19) United States
(12) Patent Application Publication
(10) Pub. No.: US 2005/0130397 A1
(43) Pub. Date: Jun. 16, 2005

(54) Formation of layers on substrates

(76) Inventors: Philip Gareth Bentley, Cambridge (GB); James Edward Fox, Cambridge (GB); Alan Lionel Hudd, Nuthampstead (GB); Martyn John Robinson, Cambridge (GB)

Correspondence Address: MORGAN LEWIS & BOCKIUS LLP, 1111 PENNSYLVANIA AVENUE NW, WASHINGTON, DC, 20004, US

(21) Appl. No.: 10/975,499

(22) Filed: Oct. 29, 2004

Related U.S. Application Data
(60) Provisional application No. 60/527,948, filed on Dec. 8, 2003.
(60) Provisional application No. 60/540,080, filed on Jan. 28, 2004.

(30) Foreign Application Priority Data
Oct. 29, 2003 (GB) 0325247.5
Dec. 5, 2003 (GB) 0328221.7
Jan. 24, 2004 (GB) 0401826.3

(51) Int. Cl. H01L 21/20

(52) U.S. Cl. 438/584

(57) ABSTRACT

Disclosed is a method of forming, on the surface of a substrate, a first layer which is suitable for activating a second solid-layer-forming chemical reaction thereon, the method comprising the steps of bringing into contact with the substrate a first liquid which forms a first solid layer thereon, the first liquid comprising an activator for the second solid-layer-forming chemical reaction, characterised in that the first liquid is selected so that the first solid layer adheres to the substrate and is permeable to a second liquid that comprises one or more reagents for the second solid-layer-forming chemical reaction. A second solid layer can then be formed on the substrate by bringing into contact with the first solid layer a second liquid comprising one or more reagents for the second solid-layer-forming reaction.

The present invention relates to the formation of solid layers on substrates, particularly, but not exclusively, the formation of conductive metal regions on substrates by the reduction of metal ions. In this specification, the adjective solid, in the context of a solid layer, or solid substrate, refers to being in the solid (rather than liquid or gas) phase of matter. A solid layer or substrate may be plastic, elastic, resilient, rigid, gelatinous, permeable, or have any other property consistent with being solid phase.

### BACKGROUND TO THE INVENTION

There are many industrial applications for conductive metal regions on substrates, particularly processes which enable the conductive metal regions to be formed according to a pattern. An important application is the manufacture of printed circuit boards, upon which metal layers are formed into a pattern to electrically connect different components and electrical devices according to a predetermined arrangement. Other applications include aerials and antennae, such as those found in mobile telephones, radio frequency identification devices (RFIDs), smart cards, contacts for batteries and power supplies, arrays of contacts for flat screen technologies (liquid crystal displays, light emitting polymer displays and the like), electrodes for biological and electrochemical sensors, smart textiles, and decorative features.

In most of these applications, the metal region must be conductive and a high level of conductivity is desirable, or in some cases essential.

It is known to form conductive metal regions on substrates by the reduction of metal ions. This is the basis of the so-called “electroless” plating procedure in which a catalyst is applied to a substrate which is then immersed in a succession of baths. One of the baths comprises a metal ion (e.g. a copper salt), a reducing agent (e.g. formaldehyde) and a base to activate the formaldehyde (e.g. sodium hydroxide). The metal ion is reduced to form a conductive metal region on the substrate surface, where the catalyst has been applied.

In our International Patent Application No. PCT/GB2004/000358 (WO 2004/068389), we have proposed an alternative to immersion procedures, in which metal ion and reducing agent are deposited together on a substrate, preferably by inkjet printing, and react in situ to form a conductive metal region.

In both immersion and deposition-based metallisation techniques, it is important to ensure that conductive metal forms on the surface of the substrate, where it is intended, rather than as fine metal particles in solution. Once fine metal particles form in a solution of metal ions and reducing agent, they will rapidly expand, and the metal will plate out without adhering to the substrate. It can be quite difficult to formulate a metallisation solution such that it is able to deposit where it is required, but remains stable.

Where a catalyst, or any other species which can activate the metallisation technique is applied to the substrate, this will dispose the metal ions in solution to deposit on the catalyst or activator. However, this will only work effectively if the activator adheres to the substrate; otherwise, fine metal particles may well be formed, or no metallisation may occur.

One approach known in the art of printing to improve adhesion of material to substrates is to deposit a binder with the active material (here the activator), thereby retaining the activator on the surface. However, it is difficult to do this without the binder blocking access to the catalyst by the metallisation solution.

Another solution is to deposit the catalyst with an aggressive solvent which dissolves or otherwise penetrates the substrate, allowing activator to enter into the substrate. This is particularly useful for substrates which are not otherwise permeable to the metallisation solution. However, it is difficult to achieve both good adhesion of the resulting metal layer whilst leaving the activator sufficiently accessible to activate the metallisation reaction.

U.S. Pat. No. 5751325 discloses an inkjet printing process for producing high density images on a substrate, in which the substrate may be provided with an ink-receiving layer containing a permeable film-forming binder, e.g. poly(acrylic acid) or polyvinlypyrrolidone, a reducing agent and/or development nucleii, e.g. silver sulphide-nickel sulphide. An ink containing a reducible metal salt, e.g. an aqueous solution of a silver salt, may be inkjet printed onto the ink-receiving layer.

WO 03/021004 discloses production of thin film porous ceramic-metal composites on substrates, particularly for catalysts and gas sensors. In one embodiment, patterned nickel coated polyimide sheet was prepared by spin coating the sheet with a solution of zirconium propionate, aluminium 2-ethylhexanoate and palladium acetate in tetrahydrofuran, and allowing the solvent to evaporate, producing a layer of palladium-containing zironica/alumina. The ceramic layer was patterned by exposure to UV light through a photomask, followed by washing in an actone/isopropanol mixture to remove unexposed parts of the coating. The patterned substrate was treated at 350° C. for 2 minutes, then allowed to cool. Nickel plating was performed by immersion in electroless plating solution.

WO 2004/068918 concerns the production of thin silver layers on printed circuit boards to minimise skin effect losses. The dielectric substrate of a printed circuit board is coated with a polymer, particularly polyimide, which is then coated with a solution containing zirconium propionate and preferably also palladium acetate. The substrate is heated at temperatures at least 120° C. for at least 20 minutes to dry the coating, and then a layer of silver is formed thereon by immersion in electroless silver plating solution.

### SUMMARY OF THE INVENTION

According to the present invention there is provided a method of forming, on the surface of a substrate, a first layer which is suitable for activating a second solid-layer-forming chemical reaction thereon, the method comprising the steps of bringing into contact with the substrate a first liquid which forms a first solid layer thereon, the first liquid comprising an activator for the second solid-layer-forming chemical reaction, characterised in that the first liquid is selected so that the first solid layer adheres to the substrate and is permeable to a second liquid that comprises one or more reagents for the second solid-layer-forming chemical reaction.

The invention also extends to a method of forming a layer of material on a substrate, the method comprising the steps of: bringing into contact with the substrate a first liquid which forms a first solid layer on the substrate, the first liquid comprising an activator for a reaction that forms said solid layer of material on the substrate, and bringing the first solid layer into contact with a second liquid comprising one or more reagents for the (second) solid-layer-forming reaction, wherein the first liquid is selected so that the first solid layer adheres to the substrate and is permeable to the second liquid, thereby enabling the second liquid to penetrate the first solid layer, bringing the one or more reagents of the second solid-layer-forming reaction into contact with the activator for reaction to form the (second) solid layer of material.

In accordance with the invention there is provided a method of forming, on the surface of a substrate, a first solid layer which is capable of activating a chemical reaction to form a second solid layer thereon, the method comprising bringing into contact the substrate surface and a first liquid to form said first solid layer adhering to the substrate surface, the first liquid, and the first layer, including an activator for said chemical reaction, and the first solid layer being permeable to a second liquid that comprises one or more reagents for the chemical reaction forming the second solid layer, wherein the first layer includes a first chemical functionality which is at least partially insoluble in the second liquid.

The method conveniently includes formation of the second solid layer on the first solid layer. The method thus preferably further comprises bringing into contact the first solid layer and the second liquid to form the second solid layer. The second liquid permeates or penetrates the first layer, bringing the second liquid into proximity or contact with the activator, for reaction to form the second solid layer.

Thus, in a preferred aspect the invention provides a method of forming first and second superposed solid layers of material on the surface of a substrate, the method comprising bringing into contact the substrate surface and a first liquid to form a first solid layer adhering to the substrate surface, the first liquid, and the first layer, including an activator for a second solid layer-forming reaction, and bringing into contact the first solid layer and a second liquid comprising one or more reagents for reaction to form the second solid layer, wherein the first layer is permeable to the second liquid, so that the second liquid permeates or penetrates the first layer, bringing said one or more reagents of the second liquid into proximity or contact with the activator for reaction to form the second solid layer on the first layer, and wherein the first layer includes a first chemical functionality which is at least partially insoluble in the second liquid.

In the methods of the invention, the activator is adhered to the substrate by virtue of its inclusion in the first solid layer (whether by entrapment, immobilisation or other means).

When the second liquid is brought into contact with the first solid layer, the second liquid penetrates the first solid layer, allowing the second liquid to access the activator within the first solid layer. The second solid-layer-forming reaction can thus take place on, or in close proximity to, the substrate substance, producing the desired second solid layer of material on the substrate. Furthermore, penetration of the second liquid into the first solid layer may result in the second solid layer of material intermingling with the first solid layer, thereby enhancing adhesion of the second solid layer of material to the substrate via the adhered first solid layer.

The second solid layer of material is conveniently a conductive metal layer, which may be formed by a variety of different processes involving the activator in the first layer. The processes typically involve the reduction of metal ions, and include electroless plating, as referred to above, and the process disclosed in WO 2004/068389.

As the activator is located in a layer on the surface of the substrate, the second reaction, e.g. metallisation, will occur on or in the first layer in preference to reaction, e.g. the formation of fine particles of metal, in the second liquid.

The second liquid may be in the form of one or more components, that may be applied to the first solid layer simultaneously or sequentially.

The first layer need not be directly adhered to the substrate surface: there may be one or more intervening layers. Further, the second layer need not be the top or final layer: one or more further layers may be formed thereon.

Because the first layer includes a first chemical functionality which is at least partially insoluble in the second liquid, the physical integrity of the first layer is maintained on contact with the second liquid and while the second solid layer is formed. This has the consequence of improving adhesion of the second solid layer with respect to the substrate surface. The first chemical functionality need not be completely insoluble in the second liquid, but merely sufficiently insoluble to achieve this effect. Thus, the first chemical functionality only needs to be sufficiently insoluble in the second liquid to retain the integrity of the first layer while the second solid layer is formed.

The first chemical functionality also functions to adhere the first layer to the substrate, and so is selected having regard to the substrate. Adhesion can arise through chemical bonding, physical bonding, mechanical bonding or a mixture thereof.

The second liquid is preferably aqueous, as will be discussed below, so the first chemical functionality is preferably at least partially insoluble in water. The first chemical functionality may be present in the first liquid, and also in the first layer, or may be formed, e.g. by cross-linking, in the first layer from reactants (that are possibly soluble in the second liquid) in the first liquid. The first chemical functionality is preferably non-ceramic. The first chemical functionality is preferably at least predominantly or fully organic and/or silicon based, comprising at least 50% by weight of organic and/or silicon materials, for improved adhesion to a wide range of organic substrates such as plastics substrates. The first chemical functionality may absorb the second liquid and swell. Suitable first chemical functionalities include polyvinly butyral (PVB), which may be included as an ingredient of the first liquid. This gives good adhesion to a wide range of substrates including plastics substrates such as polyesters. The first chemical functionality may also be constituted by the reaction product of one or more curable monomers and/or oligomers in the first liquid, e.g. as discussed below, including Actilane 505 (a reactive tetrafunctional polyester acrylate oligomer—Actilane is a Trade Mark), DPHA (dipentaerythritol hexaacrylate) and DPGDA (dipropylene glycol diacrylate). Such materials may be included in the first liquid and react to form a polymer in the first layer with appropriate solubility properties. The polymer product also has good adhesion to a very wide range of substrates, including metals, glass, ceramics and plastics materials. Thus, the first liquid includes one or more ingredients that constitute or form the first chemical functionality in the first layer.

The first liquid is typically in the form of a solution, preferably a non-aqueous solution as mentioned above, but may alternatively be in the form of a suspension or dispersion with one or more components in solid or colloidal form. The first liquid includes a solvent or carrier liquid, which is preferably non-aqueous. Preferred non-aqueous liquids are discussed below.

The second liquid may be in the form of a solution, preferably an aqueous solution as mentioned above, but may alternatively be in the form of a suspension or dispersion with one or more components in solid or colloidal form. The second liquid includes a solvent or carrier liquid, which preferably comprises water.

The first and second liquids thus preferably comprise different solvents or carrier liquids.

The activator is preferably a catalyst, such as palladium for catalysing a metallisation reaction. However, the activator could instead comprise a chemical species which can activate the second solid layer forming chemical reaction, but is consumed or reacts in the process and so is not strictly speaking a catalyst.

The activator may alternatively comprise a reagent or a plurality of reagents which, when brought into contact with the second liquid, undergo(es) a chemical reaction leading to formation of the second solid layer on the first solid layer.

The activator may be applied in precursor form. In this case, the method may include the further step of chemically converting the one or more precursor reagents to an active or catalytic form. For example, palladium acetate may be reduced in situ by a subsequently applied reducing agent solution, forming palladium metal which can catalyse deposition of metal thereon when an appropriate second liquid is applied.

The first layer preferably comprises a second chemical functionality which is at least partially soluble or swellable in the second liquid or permeable to the second liquid. The second liquid is preferably aqueous, as noted above, so the second chemical functionality is preferably at least partially soluble or swellable in water or permeable to water. The second chemical functionality may be present in the first liquid, and also the first layer, or may be formed in the first layer from reactants in the first liquid. Suitable second chemical functionalities are discussed below, and include polyvinylpyrrolidone (PVP), which is soluble in water, and which may be included as an ingredient of the first liquid. The second chemical functionality will at least partially dissolve or swell in, or be permeable to, the second liquid, allowing the liquid solvent to penetrate the first solid layer and contact the activator. The first chemical functionality retains sufficient integrity to adhere to the substrate and the second solid layer, resulting in a “sponge-like” structure.

The first and second chemical functionalities may be separate molecules, or groups of molecules, or may be or become part of the same molecules. Typically, they are two separate binders.

The first liquid desirably includes a solvent that is sufficiently aggressive to the substrate to allow the first liquid to penetrate therein, increasing adhesion of the first solid layer to the substrate, and thus also increasing the adhesion of the second solid layer to the substrate (via the first solid layer).

The first liquid may be curable, as is discussed below.

The first and second liquids are preferably based on different solvents, as mentioned above. This allows the first solvent to be selected to be appropriate for the formation of the first layer and the adhesion of the first layer to the substrate, whilst the second solvent can be selected to be appropriate for the formation of the second layer. Preferably, the second solvent is water. Preferably also, the first solvent is selected to partially dissolve or otherwise permeate into the substrate, as noted above, improving adhesion of the first layer to the substrate. Thus, aqueous metallisation chemistry and a non-aqueous first solvent can be utilised in different steps of the same process. Preferably, the first solvent is partially or entirely non-aqueous. The first liquid may be curable as discussed below.

The first chemical functionality may conveniently be polyvinyl butyral (PVB) which is insoluble in water. Where the first chemical functionality is the binder polyvinyl butyral and the second chemical functionality is the binder polyvinylpyrolidone (PVP), appropriate relative amounts of the two binders in the first liquid can be readily determined to suit requirements.

As mentioned above, the first liquid may comprise one or more ingredients that constitute or form in the first layer a second chemical functionality which is soluble or swellable in the second liquid. One preferred second chemical functionality is polyvinylpyrrolidone (PVP), which is soluble in water. PVP may be included as an ingredient of the first liquid. Alternatives for the second chemical functionality include polyacrylic acid, polyvinyl acetate, polyethylene imine, polyethylene oxide, polyethylene glycol, gelatin or copolymers thereof. The soluble components may dissolve when the second liquid is brought into contact with the first solid layer. For example, polyvinylpyrrolidone will dissolve in contact with an aqueous solution of metal ion and reducing agent usable to form a conductive metal region on the first solid layer. Good results have been obtained with use of up to around 50% by weight of polyvinylpyrrolidone in the resulting solid first layer, with suitable quantities depending on the other chemistry involved, particularly the nature of the first chemical functionality. For curable first liquids, to be discussed below, the first solid layer conveniently includes about 5 % by weight of PVP.

The second chemical functionality could instead (or as well) comprise a water swellable monomer and/or oligomer such as HEMA (2-hydroxyethyl methacrylate), GMA (glyceryl methacrylate) or NVP (n-vinyl pyrrolidinone). Other monomers and/or oligomers which are themselves swellable in the solvent of the second liquid and/or are swellable when polymerised could be used instead. This allows the second liquid to permeate into the first solid layer, improving adhesion and allowing access to more activator than just what is present on the surface of the first solid layer.

The second chemical functionality could instead (or as well) comprise a high boiling point solvent miscible with the solvent of the second liquid. For example, NMP (n-methyl pyrrolidinone) could be used when the second liquid is aqueous. This keeps the resulting polymer matrix open in the first solid layer allowing penetration by the second liquid and improving the adhesion of the second solid layer to the first solid layer.

The first liquid could instead (or as well) comprise micro-porous particles to create a micro-porous film structure. Micro-porous particles could be organic (e.g. PPVP poly (polyvinyl pyrrolidinone)) or inorganic (e.g. silica).

The first liquid may solidify as a result of evaporation of the first solvent, or as a result of curing.

The first solid layer may coat most or all of the entire substrate surface. Alternatively, the first solid layer may be formed on the substrate according to a desired pattern. This may be achieved in several ways. For example, the first liquid may be deposited according to a pattern, e.g. by printing in the desired pattern, particularly by inkjet printing. Alternatively, the first solid layer may be patterned after the first liquid has been deposited; for example, the first liquid may be applied extensively across the substrate, caused selectively to harden according to a pattern (for example, by a masking technique), with unhardened liquid then removed.

Thus, the use of a first liquid which hardens to form a first solid layer allows patterning to an extent which would not be possible were the activator deposited on the substrate as a liquid which remained soft and flowed.

The first liquid can be applied extensively to a substrate surface by a wide range of possible techniques, including using printing, dipping, spraying and spinning techniques such as jet printing, inkjet printing, spin coating, dip coating, spray coating, aerosol spraying, roller coating, curtain coating, screen printing, litho printing, flexo printing, gravure printing and pad printing, or by any other liquid application technique. The first liquid is preferably applied as a single liquid, for example, by inkjet printing from a single liquid reservoir.

Preferably, the first liquid is brought into contact with the substrate by a deposition process, for example a printing process. Preferably, the deposition process is a non-contact process that is preferably digital e.g. inkjet printing.

Typically, print quality and adhesion are governed predominantly by the properties of the first liquid and the first solid layer which it forms. Thus, to some extent, the invention allows the first liquid to be selected dependent on the patterning quality required and the second liquid to be selected dependent on the desired properties of the (second) solid layer of material. This can allow greater flexibility in designing appropriate first and second liquid chemistries for a particular application.

The process may be repeated (optionally with different first and second liquids) to build up a multi-layer structure.

Preferably, the first liquid is curable; that is to say, able to undergo a chemical change as a result of which the liquid hardens, preferably solidifies

Use of a curable first liquid enables the liquid to be selected to have improved wetting properties on one or more substrates as compared with those of the second liquid. This allows more accurate and precise patterning than if the curable first liquid was applied from the same carrier (e.g. water) as the second liquid, with fine features and better edge definition being possible. There will typically be less bleed and feathering of the curable first liquid than if activator were applied to the surface by a different technique using a carrier with poorer wetting properties. Improved wetting properties allow more accurate and precise patterning as successive spots of liquid along a line can be deposited further apart (by a technique such as inkjet printing) allowing a lower volume of liquid to be used, and thus narrower lines and finer features to be prepared. Use of a curable first liquid can also result in improved adhesion of the first solid layer to the substrate surface.

This use of the curable first liquid comprising an activator is particularly important where it is desirable to use inkjet printing to digitally pattern a material on a substrate. Many curable liquids are within the correct viscosity range to be inkjet printed.

The curable first liquid preferably comprises one or more component chemicals which can undergo a reaction causing the liquid to harden.

Preferably, the curable first liquid comprises one or more monomers and/or oligomers which can polymerise and/or cross-link in use, thereby hardening and forming a solid layer. Such monomers and/or oligomers may constitute precursors for the first chemical functionality which is at least partially insoluble in the second liquid. Preferably, the resulting polymer forms a matrix which includes the activator. A curable first liquid including at least some oligomers will often have lower toxicity than if it included only monomers.

The first solid layer may be rigid, elastic or plastic (whether or not it is formed by curing). The first solid layer need not necessarily finish hardening before the second liquid is applied.

Preferably, the first liquid is curable in response to a stimulus, for example, electromagnetic radiation of a particular wavelength band (e.g. ultra-violet, blue, microwaves, infra-red), electron beams, or heat. Thus, the curable first liquid may be curable responsive to electromagnetic radiation of a specific wavelength range (e.g. ultraviolet radiation, blue light, infra-red radiation), heat curable, electron beam curable etc. The liquid could be curable responsive to the presence of one or more chemical species such as moisture or air. Preferably, the component chemicals are selected to undergo a reaction responsive to one of the above stimuli. A ultra-violet curable first liquid is currently preferred.

It is preferred to use a first liquid such that no significant or substantial heating is required. This means that the method of the invention can be used with a wide range of substrates, including heat-sensitive plastics materials and other materials that cannot be used in the methods disclosed in WO 03/021004 where heating to 350° C. is required. In particular, it is preferred that the first layer is formed at temperatures below about 300° C. (allowing the use of polyimide substrates), desirably below about 200° C. (allowing the use of polyester substrates such as Teonex (Teonex is a Trade Mark)), more desirably below about 100° C. (allowing use of a wide range of themoplastic substrates), yet more desirably below about 50° C. (allowing use of low Tg substrates) and possibly at room temperature, avoiding the need for heating. Heating, if required, is only applied for a relatively short time, typically less than 15 minutes and preferably less than about 2 minutes for processing efficiency.

Masking can be effected by applying the curable first liquid extensively across the substrate, and applying the stimulus according to a pattern.

Typically, the curable first liquid comprises one or more monomers and/or oligomers which can form a polymer, and constitute the first chemical functionality. For example, the first liquid may comprise monomers and/or oligomers which react to form a polymer, and an initiator which starts a polymerisation reaction responsive to one of the above stimuli. For example, AIBN (2,2′-azobisisobutyronitrile) can be included to initiate a polymerisation reaction responsive to heat. Typically, an initiator generates free radicals responsive to a stimulus. Other curing processes may be used, such as cationic curing where an initiator generates cations.

Conveniently, the monomers and/or oligomers are those known from the field of UV curable, or other curable inks proposed for inkjet printing of curable inks.

Preferably, the curable first liquid comprises some monomers and/or oligomers having a high number of cross-linkable functional groups, such as four or more, or even six or more functional groups. For example, Actilane 505 (which is a reactive tetrafunctional polyester acrylate oligomer supplied by Akzo Nobel UV Resins, Manchester, UK—Actilane is a Trade Mark) is suitable, as are DPHA (dipentaerythritol hexaacrylate) which is a hexafunctional monomer supplied by UCB, Dragenbos, Belgium and DPGDA (dipropylene glycol diacrylate), a reactive diluent monomer supplied by UCB, Dragenbos, Belgium. These monomers and/or oligomers with a high number of cross-linkable functional groups are more highly cross-linked than polymers formed from monomers with fewer cross-linkable functional groups and can provide a stronger, more robust film with better adhesion to the substrate. Too high a proportion of highly cross-linkable monomers and/or oligomers would however form a brittle surface.

Where the first liquid is curable, it preferably does not include a volatile carrier which, in use, is evaporated off before the second liquid is brought into contact with the first layer. Thus, substantially all of the constituents of such a curable first liquid preferably remain (albeit perhaps in chemically changed form) in the first solid layer.

Preferably, the delay between depositing and curing the curable liquid is as short as possible. This reduces over-wetting of the substrate, which causes loss of definition to the image. Preferably the delay between deposition and curing is 20 seconds or less.

However, the first liquid may include a volatile carrier. Typically, in use, some or all of the volatile carrier (if present) evaporates or is evaporated off before the second liquid is brought into contact with the first layer. For example, the first liquid may comprise water or (preferably) one or more organic solvents which, in use, are evaporated off before the second liquid is brought into contact with the first layer. The method in this case may include a pause to allow a volatile carrier to evaporate before one or both of applying a stimulus (if applicable) and bringing the second liquid into contact with the first layer.

As the activator is also included in the first liquid it will typically be trapped within the first layer in a matrix formed, for example, by a polymer. The activator could also be immobilised as part of the matrix, for example, by including the activator on a molecule with a reactive group which reacts with monomer or oligomer units. The activator may be initially inactive, and become active only once the first liquid has formed the first solid layer, or in response to a stimulus, or when in contact with a component of the second liquid.

The invention finds particular application in the production of layers of conductive metal as the second solid layer. Conductive metal layers are typically formed by the reduction of metal ions in a reaction involving a catalyst, a metal ion and a reducing agent. A variety of different techniques may be used, including electroless plating and the process disclosed in WO 2004/068389. One reagent of the process, typically the catalyst, is deposited on a substrate (typically by inkjet printing) in the first layer by the method of the invention, and other necessary reagents deposited (by inkjet printing, immersion or otherwise) in the second liquid (and possibly in one or more other vehicles) resulting in reaction to form a conductive metal layer constituting the second solid layer.

In embodiments of the invention where the second layer is a conductive metal region, formed by the reaction of metal ions and a reducing agent, the activator conveniently comprises a catalyst or catalyst precursor comprising a salt of a conductive metal, preferably an organic acid salt of a transition metal, for example palladium acetate or palladium propanoate. The current preferred activator is palladium acetate, which is suitably present in the first liquid in an amount in the range 1 to 3% by weight, typically 2% by weight of the deposited liquid. An equivalent concentration of another organic acid salt of a transition metal can be employed. Alternative materials for this purpose include other palladium salts, such as palladium chloride, and salts, complexes or colloids of transition metals, or metal particles, such as particles of bronze, aluminium, gold or copper.

A suitable solvent for the deposition of an organic acid salt of a transition metal, e.g. palladium acetate, is a 50/50 mixture of equal parts by weight of diacetone alcohol and methoxy propanol. An alternative solvent is a 50/50 mixture of equal parts by weight of toluene and methoxy propanol. Approximately a 2% by weight solution of palladium acetate in this solvent is preferable. Preferably a co-solvent is added to increase viscosity for inkjet printing.

Where the activator is a catalyst or catalyst precursor, the second liquid conveniently comprises a solution of a metal ion and a reducing agent, operable to react together, activated by the activator, to form a conductive metal region on the first solid layer. Preferably, the composition of the second liquid is such that it does not react spontaneously, but reacts only once it has been brought into contact with the activator present in the first solid layer. The second liquid may further comprise a base/acid, to activate the reducing agent.

The metal ion, the reducing agent and the optional base/acid may be deposited in two or three separate component solutions which mix together on the substrate to form a reaction solution. Further details may be as disclosed in PCT/GB2004/000358 (WO 2004/068389).

Where the second solid-layer-forming chemical reaction is to be a reaction between metal ions and a reducing agent, to form a conductive metal region, instead of being a catalyst or catalyst precursor, the activator may be one or more of metal ions, reducing agent possibly with acid/base to adjust pH if appropriate. The second liquid will be such that a second-layer-forming reaction begins when the second liquid is in contact with the first layer. Where the activator comprises metal ions, typically as metal salts or metal complexes (and perhaps also acid/base), the second liquid may comprise reducing agent, possibly with appropriate pH adjusting reagent, e.g. a base in the case of formaldehyde. The second liquid may also contain additional ions of the same or a different metal. Where the activator comprises a reducing agent (and perhaps also base or acid), the second liquid will preferably comprise metal ions, typically as metal salts or metal complexes. The second liquid may comprise further reducing agent which may be the same or different to the first reducing agent. It may be appropriate to use a more powerful reducing agent such as DMAB (dimethylamine borane) initially followed by a less powerful reducing agent such as formaldehyde which gives a more pure, higher conductivity metal layer. Where the activator comprises base/acid, the second liquid typically includes metal ions and reducing agent, and optionally further base/acid.

The metal ion may be an ion of any conductive metal, particularly a transition group metal. Preferable conductive metals include copper, nickel, silver, gold, cobalt, a platinum group metal, or an alloy of two or more of these materials. The conductive metal may include non-metallic elements, for example, the conductive metal may be nickel phosphorus.

The metal ion is typically in the form of a salt, for example copper sulphate. The metal ion might instead be present in a complex such as with EDTA (ethylene diamine tetra acetic acid) or cyanide.

Examples of appropriate reducing agents are formaldehyde, glucose or most other aldehydes, or sodium hypophosphites, or glyoxylic acid or DMAB (dimethylamineborane).

Preferably, the first liquid is deposited onto the substrate by inkjet printing. The second liquid may be deposited on the first layer by inkjet printing or other techniques. Where the first liquid and/or resulting first layer are patterned, the second liquid may be deposited according to the same pattern.

As inkjet printing processes are typically digitally controlled, different patterns can be applied using the same apparatus to different substrates. This is particularly important for the production of one-off products, customised products, or a series of uniquely identifiable products.

Optionally, the substrate is preheated before an activator liquid is deposited thereon. This causes the activator liquid to dry rapidly and spread less, achieving thinner lines. For example, a Melinex polyester substrate (Melinex is a Trade Mark) was heated with air at 350° C. for 4 seconds using a hot air gun.

The substrate may be selected from a wide range of possibilities, including plastics, ceramics, natural materials, fabrics etc. In embodiments where the second solid layer is a conductive metal, suitable substrates include plastics materials and fabrics, e.g. in the form of sheets. A substrate might be a material having thereon electrical components, such as conductive, semi-conductive, resistive, capacitive, inductive, or optical materials, such as liquid crystals, light emitting polymers or the like. As noted above, the method of the invention need not involve significant heating and so may be used with a wider range of substrates, including heat-sensitive plastics materials than is possible with the methods disclosed in WO 03/021004 and WO 2004/068918. The method may include the step of depositing one or more of said electrical components on the substrate, preferably by inkjet printing, prior to forming a conductive metal region on the resulting substrate.

Similarly, the method may further include the step of depositing an electrical component onto the resulting conductive metal region, building up complex devices. Said further deposition step may also be carried out using inkjet printing technology.

The invention finds particular application in printing of batteries. A battery may be formed on a substrate by forming two regions of different conductive metals on a substrate by the method of the invention, and electrolytically connecting the two regions by way of an electrolyte (which may be inkjet printed), thereby forming an electrochemical cell. A plurality of electrochemical cells may be electrically connected in series or in parallel thereby increasing the voltage and/or current available. The invention also covers a method of forming a battery by forming two regions of different conductive metals on a substrate by the method of the invention and electrolytically connecting the two regions by way of an electrolyte (which may be inkjet printed). The invention also extends to a battery formed by the said method.

Thus, the method of the invention can be used as one stage in the fabrication of electrical items. It is particularly appropriate for use in manufacturing electrical items which involve complex patterns, such as displays which include complex patterns of pixels. Other applications include the fabrication of aerials or antenna for car radios, mobile phones, and/or satellite navigation systems; radio frequency shielding devices; edge connectors, contact and bus connectors for circuit boards; radio frequency identification tags (RFID tags); conductive tracks for printed circuit boards, including flexible printed circuit boards; smart textiles, such as those including electrical circuits; decorations; vehicle windscreen heaters; components of batteries and/or fuel cells; ceramic components; transformers and inductive power supplies, particularly in miniaturised form; security devices; printed circuit board components, such as capacitors and conductors; membrane keyboards, particularly their electrical contacts; disposable, low cost electronic items; electroluminescent disposable displays; biosensors, mechanical sensors, chemical and electrochemical sensors.

The method also finds application in producing an electrical connection between two components for a circuit.

The method may include the further step of forming an additional metal layer onto a conductive metal region constituted by the second layer, e.g. by electrolytic or electroless plating or by immersion metallisation.

Where the first liquid, and/or the second liquid, are inkjet printed, the respective liquids should fulfil the specific requirements of inkjet printing inks as regards viscosity, surface tension, conductivity, pH, filtration, particle size and ageing stability. One or more humectants may be added to one or more component solutions to reduce evaporation. The particular values of these properties which are required are different for different inkjet technologies and suitable component solutions fulfilling these properties can readily be devised for a specific application by one skilled in the art.

The method also extends to an article prepared according to the method of the invention.

According to a further aspect of the present invention there is provided an activator liquid which is suitable for activating the formation of a (second) solid layer on a substrate, the liquid comprising an activator suitable for activating a (second) solid layer forming chemical reaction, and being selected so that the activator liquid solidifies and adheres to the substrate, forming a (first) solid layer which is permeable to a second liquid that comprises one or more reagents which, when activated by the activator, can undergo reaction to form a second solid layer.

The invention also provides an activator liquid which is suitable for production on a substrate of a first solid layer for activating the formation of a second solid layer, the liquid comprising an activator suitable for activating a second solid layer-forming chemical reaction, and the liquid being such that, in use, on application to a substrate, the activator liquid solidifies and adheres to the substrate, forming a first solid layer which is permeable to a second liquid that comprises one or more reagents which, when activated by the activator, can react to form a second solid layer, the activator liquid including one or more reagents that constitute or form in the first layer a first chemical functionality which is at least partially soluble in the second liquid.

The invention also covers the activator liquid in combination with a suitable second liquid.

Preferred features of the layer-forming activator solution are as discussed above in relation to the first liquid with preferred features of the second liquid being as discussed above.

The invention will be further described, by way of illustration, in the following Examples. In the Examples all percentages are percentages by weight unless otherwise specified.

### EXAMPLE 1

Conductive copper regions were formed on substrates of various different materials by the following procedure.

An activator solution with the following composition was prepared:

| | % |
|---|---|
| palladium acetate | 2.0 |
| diacetone alcohol | 47.5 |
| methoxy propanol | 47.5 |
| polyvinyl butyral (PVB) | 1.6 |
| polyvinylpyrrolidone (PVP) | 1.4 |

Palladium acetate is present as an activator (catalyst). Diacetone alcohol and methoxy propanol are mixed in equal proportions by weight to give a solvent which evaporates sufficiently quickly to allow the palladium acetate to attach to the substrate before addition of the reaction solutions discussed below. However, the rate of evaporation is sufficiently slow that this activator solution can be conveniently inkjet printed.

Polyvinyl butyral (PVB), functioning as a first chemical functionality, is insoluble in water and is present to help the activator adhere to the substrate. Polyvinyl butyral with a molecular weight of between 15,000 and 25,000 is suitable, such as grade BN18, available from Wacker.

Polyvinylpyrrolidone (PVP), functioning as a second chemical functionality, is water soluble and so dissolves in the aqueous metallisation solution discussed below. K30 grade polyvinylpyrollidinone was sourced from International Speciality Products. This polymer has a molecular weight between 60,000 and 70,000.

This activator solution has a viscosity of 3.85 cPs and a surface tension of 30.5 dynes per cm.

To make the above activator solution, a 30% solution of polyvinyl butyral is prepared in a 50/50 mixture by weight of diacetone alcohol and methoxy propanol. A 3% palladium acetate solution is prepared in the same solvent mixture using sonication over a period of 2-3 hours. These two solutions are then mixed and more of the same solvent mixture is added to make up the appropriate total volume to give the proportions specified above. The resulting fluid is then filtered through a 1 micron GF—B glass fibre filter available from Whatman. A slight deposit is sometimes visible on the filter paper.

Deposition

The activator solution was deposited on substrates of various different materials, as specified below, by inkjet printing using an XJ128-200 print head, from Xaar, primed with the activator solution and then used to jet the activator solution onto the substrate. The resolution down web can adjusted to the particular substrate. For easily wetted substrates, 250 dots per inch (dpi) is suitable. For substrates which are wetted only with difficulty, 1000 dpi can be used to ensure complete wetting.

The XJ128-200 print head ejects droplets of 80 μL at a jetting frequency of between 1 and 2 kHz and a throw distance of 1-2 mm.

After jetting of the activator solution, the printed activator solution was permitted or caused to dry to form a first solid layer on the substrate, e.g. using an infra-red heater located just above the substrate, with the surface temperature of the substrate not exceeding about 50° C. The printed activator solution can alternatively be allowed to dry without any additional heating. Where the infra-red heater was used, 30 seconds is a typical drying time.

Metallisation

A metallisation solution was then applied to the dried activator solution (constituting the first solid layer) on the substrate. Application of the metallisation solution could be achieved by immersion of the substrate in a conventional electroless bath. However, in this example, the metallisation solution was deposited by inkjet printing.

The metallisation solution was composed of the following 3 component solutions, A, B and C.

Solution A

| | % |
|---|---|
| copper sulphate | 1.63 |
| sodium sulphate | 3.21 |
| EDTA, disodium salt | 0.60 |
| water | 89.56 |
| t-butanol | 5.00 |

The copper sulphate is the source of the metal ion, here Cu²⁺. Sodium sulphate is present to stabilise the copper sulphate. EDTA is a complexing agent which forms a protective barrier around the copper ions, without which a solution of this composition would immediately precipitate out t-butanol is a cosolvent which reduces surface tension and improves wetting.

Solution B

| | % |
|---|---|
| formaldehyde solution (37% by weight in water) | 0.22 |
| sodium formate | 3.71 |
| water | 91.07 |
| t-butanol | 5.00 |

Formaldehyde is present as a reducing agent.

Solution C

| | % |
|---|---|
| sodium hydroxide | 1.74 |
| water | 93.26 |
| t-butanol | 5.00 |

The function of sodium hydroxide is to activate the reducing agent when the solutions are combined.

Solutions A, B and C were shaken and then filtered through a 1 micron GF—B glass fibre filter, available from Whatman. Each solution had a viscosity of less than 3 cPs.

Next, the 3 separate component solutions A, B and C were separately inkjet printed onto the dried activator. The three solutions were printed separately, in equal volumes, onto the same locations on the substrate, evenly across the whole printable surface area of the substrate, with the 3 solutions combining to form a reaction solution in situ. The solutions were inkjet printed using a 64ID3 print head, available from Ink Jet Technology. All parts of this print head which contact the fluid to be jetted are ceramic and so this head is particularly suitable for printing very basic or acidic liquids. Jetting took place at 5 kHz. The waveform of the potential applied to the piezoelectric printing head was selected to cause ejection of droplets of 137 pL.

The reaction solution was allowed to remain in contact with the substrate until a suitable thickness of copper had been deposited. Typically, less than 5 minutes at room temperature were required to produce a suitable layer of copper.

It was found that the copper regions could be formed quicker by heating the substrate with infra-red radiation. However, it was important to ensure that the surface temperature did not rise above 50 degrees Centigrade for many types of plastics substrates, to avoid warping the substrate.

Finally, any excess solution or dried salts were wiped or washed off the substrate, yielding a copper-plated sample where the copper plated regions correspond to the pattern in which the activator had been inkjet printed.

Results

Copper was inkjet printed by this technique onto the following substrates, and the strength of the adhesion between the deposited conductive metal regions and the substrate was qualitatively measured.

| Substrate Material | Adhesion |
|---|---|
| acrylic | Good |
| polystyrene | Good |
| polyethylene | Poor through good, |
| | depending on grade |
| delrin polyacetal homopolymer | Poor |
| Hostaform or Ultraform | Poor |
| polyacetal copolymer | |
| ABS (Acrylonitrile | Good |
| butadiene styrene) | |
| U-PVC | Good |
| silicone rubber | Poor |

(Delrin is a trademark of DuPont. Hostaform is a trademark of Hoechst. Ultraform is a trademark of BASF.)

This Example demonstrates the printing of conductive metal regions with conductivity approximating that of bulk metal.

Metal layers of between 0.3 and 3 microns have been demonstrated depending on the specific chemistry used. Repeat printing can be used to build up thicker layers, such as the 15 to 20 micron layers required for aerial/antenna applications.

### EXAMPLE 2

This example is generally similar to Example 1, but uses a single solution, referred to as solution AB, containing both the metal ion and the reducing agent, in place of separate solutions A and B. Solution AB has the following composition:

| | % |
|---|---|
| copper sulphate | 1.63 |
| sodium sulphate | 3.21 |
| EDTA disodium salt | 0.60 |
| formaldehyde solution (37% by weight in water) | 0.22 |
| sodium formate | 3.71 |
| water | 85.63 |
| t-butanol | 5.00 |

Solution AB is filtered through a 1 micron GF—B glass fibre filter, available from Whatman.

Deposition was carried out as described in Example 1, beginning with inkjet printing of the activator solution followed by a delay while the catalyst solution solvent evaporated. Next, equal volumes of solution AB and solution C (as described in Example 1) were inkjet printed over the surface of the substrate using the 64ID3 inkjet printhead.

As before, a conductive copper region forms on the substrate.

### EXAMPLE 3

This Example is generally similar to Examples 1 and 2, but uses a single solution containing all necessary reagents for the second reaction in place of solutions A, B and C in Example 1 and solutions AB and C in Example 2.

The single solution has the following compositions:

| | % |
|---|---|
| Enplate 872 A | 24.09 |
| Enplate 872 B | 24.09 |
| Enplate 872 C | 8.03 |
| water | 13.29 |
| ethylene glycol | 20 |
| t-butanol | 5 |
| Surfadone LP-100 | 0.5 |
| PEG-1500 | 5 |

Enplate 872A contains copper sulphate. Enplate 872B contains a cyanide complexing agent and formaldehyde. Enplate 872C contains sodium hydroxide. (Enplate is a Trade Mark.) Enplate 872 A, B and C are available from Enthone-OMI and are in common use as component solutions for electroless copper plating. Ethylene glycol is present as a humectant and acts to lower surface tension. T-butanol is a cosolvent which reduces surface tension and increases wetting. Surfadone LP-100 is a wetting agent with surfactant properties. PEG-1500 functions as a humectant.

The above solution is prepared from its constituents and then filtered through a 1 micron GF—B glass fibre filter from Whatman. The viscosity is 9.8 cPs and the surface tension is 30.0 dynes/cm. The solution is stable for a period of a few hours, and can be inkjet printed as a single component solution.

The activator solution described above in Example 1 is inkjet printed according to a pattern. After a short pause (30 seconds) to allow the solvent in the activator solution to evaporate, the above single component solution is deposited by inkjet printing, either across the whole printable area of the substrate, or on top of the regions where the activator solution is inkjet printed. Thus, a copper layer forms on the surface of the substrate according to the pattern.

Alternatively, metallisation can be achieved by immersing the printed substrate into conventional electroless process metallisation baths. The printed substrate may be immersed into a bath of reducing agent, to reduce palladium acetate to palladium, and then immersed into a bath of copper ions, reducing agent and base. Alternatively, with an appropriate formulation of metallisation bath, the printed substrate can be immersed directly into a bath of copper ions, reducing agent and base.

### EXAMPLE 4

### Curable Activator Layer

UV curable catalyst formulations referred to as ALF 116 and ALF 117 were prepared according to the formulation shown in Table 1 below. The monomers and initiators used are already known from the related field of UV curable inkjet inks to have excellent curing properties and adhesion to plastic substrates. These initial formulations contain some solvent as the carrier for the palladium acetate catalyst, which was allowed to evaporate off after application of the formulation to a Melinex (Melinex is a Trade Mark) polyester substrate surface by inkjet printing using an XJ500/180 print head from Xaar, UK. The inks were then cured by the application of UV which began a curing procedure in which the monomer and oligomer components polymerised.

TABLE 1
UV curable catalyst formulations (Figures
are percentages by weight)

| Materials | ALF 116 | ALF 117 |
|---|---|---|
| Palladium acetate | 1.25 | 0.94 |
| PVP K30 | — | 2.5 |
| Diacetone alcohol | 24.38 | 23.28 |
| Methoxy propanol | 24.37 | 23.28 |
| Actilane 505 | 5 | 5 |
| DPHA | 1.5 | 1.5 |
| Irgacure 1700 | 3.25 | 3.25 |
| Irgacure 819 | 1.25 | 1.25 |
| DPGDA | 39 | 39 |

PVP K30 is a grade of polyvinyl pyrrolidinone supplied by ISP, Tadworth, UK. Actilane 505 is a reactive tetrafunctional polyester acrylate oligomer supplied by Akzo Nobel UV Resins, Manchester, UK. DPHA is dipentaerythritol hexacrylate, a hexafunctional monomer, supplied by UCB, Dragenbos, Belgium. Igracure 819 and Igracure 1700 are UV photo-initiators supplied by Ciba Speciality Chemicals, Macclesfield, UK—Irgacure is a Trade Mark. DPGDA is dipropylene glycol diacrylate, a reactive diluent monomer supplied by UCB, Drogenbos, Belgium. PVP constitutes the water soluble second chemical functionality. The monomers and oligomers, Achlane 505, DPHA and DPGDA, react to form a polymer that constitutes the water insoluble first chemical functionality.

ALF 116 cured well (with a line speed of 40 metres/minute) to give a tough scratch resistant film. However, when a copper layer forming solution (consisting of Enthone 872A (30% w/w), Enthone 872B (30% w/w), Enthone 872C (10% w/w), t-butanol (5% w/w), ethylene glycol (20% w/w) and polyethylene glycol 1500 (5% w/w). (Enthone 872A, 872B and 872C are copper plating solutions supplied by Enthone Ltd of Woking, UK)) was applied to the film, no copper was deposited. We believe that this is due to the smooth, impervious surface of the cured film, which seals the catalyst into a plastic layer and prevents it from coming into contact with the copper-layer forming solution.

In contrast, ALF 117 includes a small amount (5% by weight of dried film) of polyvinyl pyrrollidinone, which was added to the formulation with the aim that it would dissolve out of the cured layer or swell or maintain permeability upon the subsequent addition of the aqueous copper-layer forming solution, and therefore expose the catalytic sites.

As with ALF 116, this again cured very well at 40 metres/minute and this time deposited copper (at a calculated 100 nm/minute).

Drying the substrate at 60° C. for 24 hours resulted in a material having good scratch resistance properties, as good as the scratch resistance of the best catalyst formulation we know for direct bonding of a copper-layer to a plastic substrate.

This work indicated that in order to maintain the activity of the catalyst it was necessary to have some form of water solubility, swellability, or other means to enable the second liquid to penetrate the first layer. Three new formulations referred to as ALF 120, ALF 121, and ALF 124 were prepared as summarised in Table 2 below. Each of these is a variant of ALF 117 from Table 1.

TABLE 2
UV-curable catalyst formulations (Figures
are percentages by weight)

| | ALF 120 | ALF 121 | ALF 124 |
|---|---|---|---|
| Palladium acetate | 2 | 2 | 2 |
| DPGDA | 76 | 48 | 48 |
| DPHA | 3 | 3 | 3 |
| Actilane 505 | 10 | 10 | 10 |
| Irgacure 1700 | 6.5 | 6.5 | 6.5 |
| Irgacure 819 | 2.5 | 2.5 | 2.5 |
| Diacetone alcohol | — | 12.75 | 14 |
| Methoxy propanol | — | 12.75 | 14 |
| PVP K30 | — | 2.5 | — |

DPGDA is dipropylene glycol diacrylate, a reactive diluent monomer, supplied by UCB, Drogenbos, Belgium.

These inks were cured using a Fusion UV 500 Watt lamp fitted with an H bulb (Fusion is a Trade Mark), in a single pass at 10 metres/minute. After curing the inks were treated with DMAB (dimethylamineborane) solution followed by a copper-layer forming solution consisting of Enthone 872A (30% w/w), Enthone 872B (30% w/w), Enthone 872C (10% w/w), t-butanol (5% w/w), ethylene glycol (20% w/w) and polyethylene glycol 1500 (5% w/w). (Enthone 872A, 872B and 872C are copper plating solutions supplied by Enthone Ltd of Woking, UK). No copper was deposited on ALF 120 or ALF 124. However, a good uniform layer of copper was deposited on ALF 121. This copper layer was found to have good conductivity, and good adhesion to the underlying substrate. Since no copper was deposited on ALF 120 or ALF 124 this provides further evidence that the PVP material is responsible for maintaining the activity of the catalyst, and that it is likely that this occurs via the water solubility mechanism proposed above.

ALF 121 was then modified further to give an ink with good properties for deposition by inkjet printing. Two such inks, referred to as ALF 125 and ALF 126b, are shown in Table 3 below.

TABLE 3
Jettable UV ink formulations (Figures are percentages by weight)

| | ALF 125 | ALF 126b |
|---|---|---|
| Palladium acetate | 2 | 2 |
| Irgacure 1700 | 3.25 | 3.25 |
| Irgacure 819 | 1.25 | 1.25 |
| DPGDA | 61 | 48 |
| DPHA | — | 3 |
| Actilane 505 | — | 10 |
| Diacetone alcohol | 15 | 15 |
| Methoxy propanol | 15 | 15 |
| PVP K30 | 2.5 | 2.5 |
| Viscosity, cPs (25° C.) | 9.59 | 11.2 |

ALF 125 and ALF 126b both showed good inkjet printing properties using a XaarJet 128-200 print head (available from Xaar of Cambridge, England) and both gave good quality copper deposition. However, when making thicker copper samples of greater than 200 nm thickness, ALF125 blistered much more easily than ALF 126b.

This is thought to be because ALF 126b contains higher functionality materials (Actilane 505 is tetrafunctional, DPHA is hexafunctional) and so is more highly cross-linked and therefore forms a stronger, more robust film with better adhesion to the substrate.

Based on these results, it is also thought that it should be possible to replace the PVP with a water-swellable monomer such as HEMA (2-hydroxyethyl methacrylate), GMA (glyceryl methacrylate) or NVP (n-vinyl pyrrolidinone). Alternatively, a high boiling point water miscible solvent such as NMP (n-methyl pyrrolidinone), ethylene glycol, diethylene glycol or glycerol could be used to keep the UV-cured layer open, and to allow penetration by the copper solution. Alternatively, micro-porous film structure could be prepared by the use of micro-porous particles, such as silica (inorganic) or PPVP (poly polyvinyl pyrrolidinone) particles (organic).

### EXAMPLE 5

A conductive copper layer was deposited on a Melinex (Melinex is a Trade Mark) polyester substrate by the following process.

A UV-curable catalyst ink with the following composition was prepared.

| Material | Function | % Composition (wt) |
|---|---|---|
| Palladium acetate | Metal salt | 2 |
| Dipropylene glycol diacrylate | UV curable | 30.5 |
| (DPGDA) | material | |
| Actilane 505 | UV curable | 10 |
| | oligomer | |
| Dipentaerythritol hexaacrylate | UV curable | 3 |
| (DPHA) | material | |
| Irgacure 1700 | Photoinitiator | 3.25 |
| Irgacure 819 | Photoinitiator | 1.25 |
| Diacetone alcohol (DAA) | Solvent | 47.5 |
| Polyvinylpyrrolidone (PVP) K30 | Polymer | 2.5 |

The ink was applied to the substrate by inkjet printing using an XJ500/180 print head from Xaar, UK, allowed to dry and then cured by exposure to UV, as described in Example 4, resulting in formation of the first layer.

The substrate and adhered first layer were immersed in a bath of reducing agent comprising 1.6% dimethylaminoborane (DMAB) in water to reduce the palladium acetate to palladium metal, thus activating the catalyst.

The substrate was then immersed in a copper bath solution with the following composition:

| | % Composition (wt) |
|---|---|
| Enplate 872A | 10.71 |
| Enplate 872B | 10.71 |
| Enplate 872C | 3.57 |
| Water | 75 |

The Enplate solutions are as specified in Example 3, and include copper ions, reducing agent and base, resulting in palladium-catalysed reduction of copper and consequential deposition of a conductive copper layer on the substrate.

1. A method of forming, on the surface of a substrate, a first solid layer which is capable of activating a chemical reaction to form a second solid layer thereon, the method comprising bringing into contact the substrate surface and a first liquid to form said first solid layer adhering to the substrate surface, the first liquid, and the first layer, including an activator for said chemical reaction, and the first solid layer being permeable to a second liquid that comprises one or more reagents for the chemical reaction forming the second solid layer, wherein the first layer includes a first chemical functionality which is at least partially insoluble in the second liquid.

2. A method according to claim 1, further comprising bringing into contact the first solid layer and the second liquid to form the second solid layer.

3. A method according to claim 2, wherein the second solid layer comprises a conductive metal layer.

4. A method according to claim 1, 2 or 3, wherein the activator is a catalyst or catalyst precursor.

5. A method according to claim 1, 2 or 3, wherein the activator comprises a reagent, or a plurality of reagents which, when brought into contact with the second liquid, undergoes a chemical reaction leading to formation of the second solid layer on the first solid layer.

6. A method according to claim 1, 2 or 3, wherein the first layer further comprises a second chemical functionality which is at least partially soluble or swellable in the second liquid or permeable to the second liquid.

7. A method according to claim 6, wherein said second chemical functionality comprises one or more of polyvinyl pyrrollidinone, HEMA (2-hydroxyethyl methacrylate), GMA (glyceryl methacrylate) and NVP (n-vinyl pyrrolidinone).

8. A method according to claim 6 or 7, wherein said second chemical functionality comprises a high boiling point solvent miscible with the solvent of the second liquid, which keeps the resulting polymer matrix open in the first solid layer allowing penetration by the second liquid.

9. A method according to claim 1, wherein the first liquid is sufficiently aggressive to the substrate to allow the first liquid to penetrate therein, increasing adhesion of the first solid layer to the substrate.

10. A method according to claim 1, wherein the first chemical functionality is at least predominantly organic and/or silicon based.

11. A method according to claim 1, wherein the first layer is formed at temperatures below about 300° C.

12. A method according to claim 1, wherein the first liquid is partially or entirely non-aqueous.

13. A method according to claim 1, wherein the second liquid is aqueous.

14. A method according to claim 1, wherein the first liquid comprise micro-porous particles and the first solid layer comprises a micro-porous film structure.

15. A method according to claim 1, wherein the first liquid is deposited on the substrate according to a pattern.

16. A method according to claim 15, wherein the first liquid is deposited on the substrate by inkjet printing.

17. A method according to claim 1, wherein the first liquid is coated on the substrate and a pattern applied using a mask process.

18. A method according to claim 1, wherein the process is repeated to build up a multi-layer structure.

19. A method according to claim 1, wherein the first liquid is curable, preferably UV curable.

20. A method according to claim 19, wherein the curable first liquid comprises monomers and/or oligomers which can polymerise and/or cross-link in use, thereby hardening and forming the first solid layer.

21. A method according to claim 20, wherein the resulting polymer forms a matrix which includes the activator.

22. A method according to claim 1, wherein the first solid layer is rigid, elastic or plastic.

23. A method according to claim 1, wherein the second liquid is brought into contact with the first liquid before the first liquid has completely solidified.

24. A method according to claim 1, wherein the activator comprises an organic acid salt of a transition metal.

25. A method according to claim 24, wherein the activator comprises palladium acetate.

26. A method according to claim 1, wherein the second solid-layer-forming chemical reaction is a reaction between metal ions and a reducing agent, to form a conductive metal region, and the activator may be one or more of metal ions, reducing agent or base.

27. A method according to claim 1, for use in producing a battery.

28. A method according to claim 1, for use in producing an electrical connection between two components for a circuit.

29. An article prepared according to the method of claim 1.

30. An activator liquid which is suitable for production on a substrate of a first solid layer for activating the formation of a second solid layer, the liquid comprising an activator suitable for activating a second solid layer-forming chemical reaction, and the liquid being such that, in use, on application to a substrate, the activator liquid solidifies and adheres to the substrate, forming a first solid layer which is permeable to a second liquid that comprises one or more reagents which, when activated by the activator, can react to form a second solid layer, the activator liquid including one or more reagents that constitute or form in the first layer a first chemical functionality which is at least partially soluble in the second liquid.

31. An activator liquid in accordance with claim 30, in combination with an appropriate second liquid.
